(19) United States
(12) Patent Application Publication
(10) Pub. No.: US 2014/0283937 A1
(43) Pub. Date: Sep. 25, 2014

(54) ELECTRO CONTROL MODULATOR VALVE AND SEMICONDUCTOR PRODUCTION APPARATUS USING THE SAME

(71) Applicant: Soon Chang LEE, SungNam-City (KR)

(72) Inventor: Soon Chang LEE, SungNam-City (KR)

(21) Appl. No.: 14/179,120

(22) Filed: Feb. 12, 2014

(30) Foreign Application Priority Data
Mar. 19, 2013 (KR) 10-2013-0029162

(51) Int. Cl. F16K 11/072; H01L 21/67

(52) U.S. Cl. CPC F16K 11/072; H01L 21/67121
USPC 137/625.41; 29/25.01

(57) ABSTRACT

Provided are an electronic control mixing valve and a semiconductor manufacturing apparatus using the same that are capable of controlling a temperature of a chuck base by supplying recirculation oils using a slidable mixing valve or a rotatable mixing valve, which is electrically controlled.

Accordingly, the electronic control mixing valve includes a lower region having a plurality of through-holes and introduction ports formed at lower ends of the plurality of through-holes, respectively, an upper region having the same number of openings as the plurality of through-holes and formed at a region of a lower surface facing the plurality of through-holes, and one discharge port formed at an upper surface, and a central region having one through-hole configured to bring the upper region in communication with the lower region, and slidable with respect to the plurality of through-holes such that the one through-hole brings any one of the plurality of through-holes in communication with the opening corresponding to the one of the plurality of through-holes and blocks the opening that does not correspond to the one of the plurality of through-holes, wherein the one through-hole of the central region is slidably driven by a stepping motor.

### CROSS-REFERENCE TO RELATED APPLICATION

This application claims priority to and the benefit of Korean Patent Application No. 2013-0029162, filed on Mar. 19, 2013, the disclosure of which is incorporated herein by reference in its entirety.

### BACKGROUND

1. Field of the Invention

The present invention relates to an electronic control mixing valve and a semiconductor manufacturing apparatus using the same, and more particularly, to an electronic control mixing valve and a semiconductor manufacturing apparatus using the same that are capable of controlling a temperature of a chuck base by supplying recirculation oils using a slidable mixing valve or a rotatable mixing valve, which is electrically controlled.

2. Discussion of Related Art

In general, a semiconductor device is formed by depositing and etching various thin films on a wafer. For example, when the wafer is etched, in order to uniformly maintain a required temperature on the wafer upon single etching and multi-step etching, it is very important to maintain a chuck base at a uniform temperature. As described above, in the method of maintaining the chuck base at a uniform temperature, as cooled warm water provided from a cold temperature source and heated warm water provided from a hot temperature source are appropriately supplied to the chuck base through a mixing valve, the temperature of the chuck base is uniformly maintained.

However, as conventional semiconductor equipment supplies the cooled warm water, the heated warm water, or mixed water of the cooled warm water and the heated warm water to the chuck base using a mixing valve having a single port and the cooled warm water, heated warm water or the mixed water is supplied through the single port, it is difficult to finely control and uniformly maintain the temperature of the chuck base.

### SUMMARY OF THE INVENTION

In order to solve the problems, the present invention is directed to provide an electronic control mixing valve and a semiconductor manufacturing apparatus using the same that are capable of controlling a temperature of a chuck base by supplying recirculation oils using a slidable mixing valve or a rotatable mixing valve, which is electronically controlled.

According to an aspect of the present invention, there is provided an electronic control mixing valve including, a lower region having a plurality of through-holes and introduction ports formed at lower ends of the plurality of through-holes, respectively, an upper region having the same number of openings as the plurality of through-holes and formed at a region of a lower surface facing the plurality of through-holes, and one discharge port formed at an upper surface, and a central region having one through-hole configured to bring the upper region in communication with the lower region, and slidable with respect to the plurality of through-holes such that the one through-hole brings any one of the plurality of through-holes in communication with the opening corresponding to the one of the plurality of through-holes and blocks the opening that does not correspond to the one of the plurality of through-holes, wherein the one through-hole of the central region is slidably driven by a stepping motor.

In addition, in the electronic control mixing valve according to the present invention, the plurality of through-holes and the introduction ports disposed at the lower ends of the plurality of through-holes may be constituted by the three through-holes through which cooled warm water, heated warm water and mixed water of the cooled warm water and the heated warm water are introduced, respectively, and three introduction ports disposed under the three through-holes, respectively.

Further, in the electronic control mixing valve according to the present invention, the stepping motor may be controlled by a controller, when the cooled warm water is maximally supplied, the controller may drive the stepping motor to dispose the one through-hole at the through-hole through which the cooled warm water is introduced such that the through-hole through which the cooled warm water is introduced, among the three through-holes of the lower region, comes in communication with the one through-hole of the central region, and when the heated warm water is maximally supplied, the controller may drive the stepping motor to dispose the one through-hole at the through-hole through which the heated warm water is introduced such that the through-hole through which the heated warm water is introduced, among the three through-holes of the lower region, comes in communication with the one through-hole of the central region.

Furthermore, in the electronic control mixing valve according to the present invention, the stepping motor may be controlled by a controller, when the cooled warm water is partially supplied, the controller may drive the stepping motor to dispose only a portion of the one through-hole at the through-hole through which the cooled warm water is introduced such that the through-hole through which the cooled warm water is introduced, among the three through-holes of the lower region, comes in partial communication with the one through-hole, and when the heated warm water is partially supplied, the controller may drive the stepping motor to dispose only a portion of the one through-hole at the through-hole through which the heated warm water is introduced such that the through-hole through which the heated warm water is introduced, among the three through-holes of the lower region, comes in partial communication with the one through-hole of the central region.

In addition, an electronic control mixing valve according to the present invention includes a lower region having a lower flat plate in which a plurality of openings are formed along an outer circumferential side of a lower surface, and an upper flat plate having introduction ports provided at the openings, respectively, disposed at a center of an upper surface, and having a plurality of openings disposed along an outer circumferential side of the upper surface, and an upper region having a through-hole in communication with an opening of a center of the upper flat plate and one discharge port formed on the through-hole, wherein the upper flat plate of the lower region is rotatably driven by a stepping motor.

Further, in the electronic control mixing valve according to the present invention, when any one opening of the plurality of openings disposed along the outer circumferential side of the upper flat plate overlaps any one opening of the plurality of openings of the lower flat plate, another opening of the plurality of openings of the upper flat plate may not overlap another opening of the plurality of openings of the lower flat plate.

Furthermore, electronic control mixing valve according to the present invention, the plurality of openings disposed along the outer circumferential side of the upper flat plate may be constituted by three openings, the plurality of openings of the lower flat plate may be constituted by three openings, and the introduction ports corresponding to the three openings may be constituted by three introduction ports through which cooled warm water, heated warm water, and mixed water of the cooled warm water and the heated warm water are introduced, respectively.

In addition, in the electronic control mixing valve according to the present invention, the three openings of the lower flat plate may be disposed along the outer circumferential side about a center of the upper surface at 120° intervals.

Further, in the electronic control mixing valve according to the present invention, the stepping motor is controlled by a controller, when the cooled warm water is maximally supplied, the controller drives the stepping motor to cause the one opening of the upper flat plate to overlap the opening of the lower flat plate through which the cooled warm water is introduced such that the opening through which the cooled warm water is introduced, among the three openings of the lower flat plate, comes in communication with any one opening of the three openings of the upper flat plate, and when the heated warm water is maximally supplied, the controller drives the stepping motor to cause the one opening of the upper flat plate to overlap the opening of the lower flat plate through which the heated warm water is introduced such that the opening through which the heated warm water is introduced, among the three openings of the lower region, comes in communication with any one opening of the three openings of the upper flat plate.

Furthermore, in the electronic control mixing valve according to the present invention, the stepping motor is controlled by a controller, when the cooled warm water is partially supplied, the controller drives the stepping motor to cause only a portion of the one opening of the upper flat plate to overlap the opening of the lower flat plate through which the cooled warm water is introduced such that the opening through which the cooled warm water is introduced, among the three openings of the lower flat plate, comes in partial communication with any one opening of the three openings of the upper flat plate, and when the heated warm water partially supplied, the controller drives the stepping motor to cause only a portion of the one opening of the upper flat plate to overlap the opening of the lower flat plate through which the heated warm water is introduced such that the opening through which the heated warm water is introduced, among the three openings of the lower region, comes in partial communication with any one opening of the three openings of the upper flat plate.

In addition, a semiconductor manufacturing apparatus using an electronic control mixing valve according to the present invention includes an electronic control mixing valve including a lower region having a plurality of through-holes and introduction ports disposed at lower ends of the plurality of through-holes, respectively, an upper region having the same number of openings as the plurality of through-holes and formed at a region of a lower surface facing the plurality of through-holes and one discharge port formed at an upper surface, and a central region having one through-hole configured to bring the upper region in communication with the lower region and slidable with respect to the plurality of through-holes such that the one through-hole brings any one of the plurality of through-holes in communication with the opening corresponding to the one of the plurality of through-holes and blocks the opening that does not correspond to the one of the plurality of through-holes, wherein the one through-hole of the central region is slidably driven by a stepping motor, and the plurality of through-holes and the introduction ports disposed at the lower ends of the plurality of through-holes are constituted by three through-holes through which cooled warm water, heated warm water, and mixed water of the cooled warm water and the heated warm water are introduced, respectively, and three introduction ports disposed under the three through-holes, a chuck base configured to dispose a wafer thereon and maintain a uniform temperature upon deposition of the wafer, a flowing water supply line configured to supply at least one of the cooled warm water, the heated warm water and the mixed water from the discharge port of the upper region to the chuck base, a flowing water discharge line configured to discharge the flowing water from the chuck base, a pump configured to circulate the discharged flowing water, a distributor configured to distribute the flowing water circulated by the pump to a first heat exchanger, a second heat exchanger, or the introduction port into which the mixed water is introduced, a cold temperature source configured to cool and discharge the flowing water introduced from the first heat exchanger, and a hot temperature source configured to heat and discharge the flowing water introduced from the second heat exchanger, wherein the first heat exchanger supplies the flowing water distributed by the distributor to the cold temperature source and provides the cooled warm water received from the cold temperature source to the introduction port into which the cooled warm water is introduced, and the second heat exchanger supplies the flowing water distributed by the distributor to the hot temperature source and provides the heated warm water received from the hot temperature source to the introduction port into which the heated warm water is introduced.

Further, a semiconductor manufacturing apparatus using an electronic control mixing valve according to the present invention includes an electronic control mixing valve including a lower region having a lower flat plate in which a plurality of openings are formed along an outer circumferential side of a lower surface and an upper flat plate having introduction ports provided at the openings, respectively, disposed at a center of an upper surface, and having a plurality of opening disposed along an outer circumferential side of the upper surface, and an upper region having a through-hole in communication with an opening of a center of the upper flat plate and one discharge port formed on the through-hole, wherein the upper flat plate of the lower region is rotatably driven by a stepping motor, and when any one opening of the plurality of openings disposed along the outer circumferential side of the upper flat plate overlaps any one opening of the plurality of openings of the lower flat plate, another opening of the plurality of openings of the upper flat plate does not overlap another opening of the plurality of openings of the lower flat plate, a chuck base configured to dispose a wafer thereon and maintain a uniform temperature upon deposition of the wafer, a flowing water supply line configured to supply at least one of cooled warm water, heated warm water and mixed water from the discharge port of the upper region to the chuck base, a flowing water discharge line configured to discharge the flowing water from the chuck base, a pump configured to circulate the discharged flowing water, a distributor configured to distribute the flowing water circulated by the pump to a first heat exchanger, a second heat exchanger or the introduction port into which the mixed water is introduced, a cold temperature source configured to cool and discharge the flowing water introduced from the first heat exchanger, and a hot temperature source configured to heat and discharge the flowing water introduced from the second heat exchanger, wherein the first heat exchanger supplies the flowing water distributed by the distributor to the cold temperature source and provides the cooled warm water received from the cold temperature source to the introduction port into which the cooled warm water is introduced, and the second heat exchanger supplies the flowing water distributed by the distributor to the hot temperature source and provides the heated warm water received from the hot temperature source to the introduction port into which the heated warm water is introduced.

Further, in the semiconductor manufacturing apparatus using the electronic control mixing valve, the cold temperature source may cool the flowing water distributed by the distributor to −60° C.

Furthermore, in the semiconductor manufacturing apparatus using the electronic control mixing valve, the hot temperature source may heat the flowing water distributed by the distributor to 150° C.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a general configuration view showing a semiconductor manufacturing apparatus using a slidable mixing valve according to an embodiment of the present invention;

FIG. 2 is a view showing a circulating operation of mixed water in the semiconductor manufacturing apparatus using the slidable mixing valve according to the embodiment of the present invention;

FIG. 3 is a view showing a circulating operation of cooled warm water maximally introduced into the semiconductor manufacturing apparatus using the slidable mixing valve according to the embodiment of the present invention;

FIG. 4 is a view showing a circulating operation of cooled warm water partially introduced from the semiconductor manufacturing apparatus using the slidable mixing valve according to the embodiment of the present invention;

FIG. 5 is a view showing a circulating operation of heated warm water maximally introduced from the semiconductor manufacturing apparatus using the slidable mixing valve according to the embodiment of the present invention;

FIG. 6 is a view showing a circulating operation of heated warm water partially introduced from the semiconductor manufacturing apparatus using the slidable mixing valve according to the embodiment of the present invention;

FIG. 7 is a general configuration view of the semiconductor manufacturing apparatus using a rotatable mixing valve according to the embodiment of the present invention;

FIG. 8 is a view showing a circulating operation of mixed water in the semiconductor manufacturing apparatus using the rotatable mixing valve according to the embodiment of the present invention;

FIG. 9 is a view showing a circulating operation of cooled warm water maximally introduced from the semiconductor manufacturing apparatus using the rotatable mixing valve according to the embodiment of the present invention;

FIG. 10 is a view showing a circulating operation of cooled warm water partially introduced from the semiconductor manufacturing apparatus using the rotatable mixing valve according to the embodiment of the present invention;

FIG. 11 is a view showing a circulating operation of heated warm water maximally introduced from the semiconductor manufacturing apparatus using the rotatable mixing valve according to the embodiment of the present invention; and

FIG. 12 is a view showing a circulating operation of heated warm water partially introduced from the semiconductor manufacturing apparatus using the rotatable mixing valve according to the embodiment of the present invention.

### DETAILED DESCRIPTION OF EXEMPLARY EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be highlighted for clarity.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section.

The terminology used herein is for the purpose of describing particular embodiments only and is not intended to be limiting the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Also, as used herein, the terms “ . . . unit,” “ . . . device,” “ . . . module,” etc., denote a unit of processing at least one function or operation, and may be implemented as hardware, software, or combination of hardware and software.

In addition, descriptions of well-known components and processing techniques are omitted so as not to unnecessarily obscure the embodiments of the present invention.

Hereinafter, an embodiment of the present invention will be described in detail with reference to the accompanying drawings.

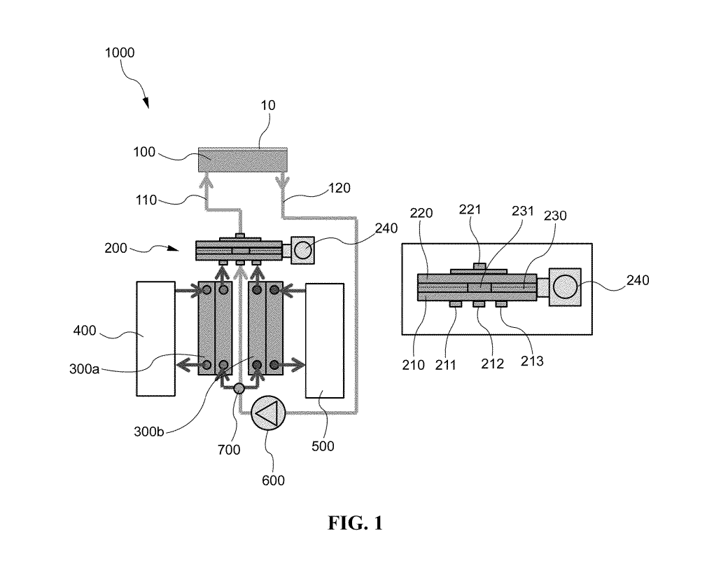

FIG. 1 is a general configuration view showing a semiconductor manufacturing apparatus using a slidable mixing valve according to an embodiment of the present invention.

Referring to FIG. 1, an electronic control mixing valve 200 according to an embodiment of the present invention includes a lower region 210 having a plurality of through-holes and introduction ports formed at lower ends of the plurality of through-holes, respectively, an upper region 220 having the same number of openings as the plurality of through-holes and formed at regions of a lower surface facing the plurality of through-holes and one discharge port 221 formed at an upper surface thereof, and a central region 230 having one through-hole 231 configured to bring the upper region 220 in communication with the lower region 210 and slidable with respect to the plurality of through-holes such that the one through-hole 231 bring any one of the plurality of through-holes in communication with an opening corresponding to the one of the plurality of through-holes and block the opening which does not correspond to the one of the plurality of through-holes, wherein the one through-hole 231 of the central region 230 is slidably driven by a stepping motor 240.

A positional relation and an operational relation thereof will be described in detail.

The electronic control mixing valve 200 according to the present invention includes the lower region 210 having the plurality of through-holes and the introduction ports formed at the lower ends of the plurality of through-holes, respectively, and the upper region 220 having the same number of openings as the plurality of through-holes and formed at a region of the lower surface facing the plurality of through-holes and having the one discharge port 221 formed at the upper surface. Here, the plurality of through-holes and the introduction ports respectively disposed at the lower ends of the plurality of through-holes may include three through-holes through which cooled warm water, heated warm water and mixed water of the cooled warm water and the heated warm water are respectively introduced, and three introduction ports disposed under the three through-holes, respectively. However, the number of through-holes and the number of introduction ports disposed under the through-holes are not limited thereto.

In addition, the central region 230 is further provided between the upper region 220 and the lower region 210. The central region 230 includes the one through-hole 231 configured to bring the upper region 220 in communication with the lower region 210. The one through-hole 231 brings any one of the plurality of through-holes in communication with the opening corresponding to any one of the plurality of through-holes. In addition, the one through-hole 231 of the central region 230 slides with respect to the plurality of through-holes to block the openings that do not correspond to the any one of the plurality of through-holes.

That is, the one through-hole 231 configured to bring the upper region 220 in communication with the lower region 210 is installed at the central region 230. When the one through-hole 231 bring any one of the plurality of through-holes in communication with the opening corresponding to the one of the plurality of through-holes, the other openings of the plurality of through-holes are blocked from the other through-holes.

As described above, the one through-hole 231 of the central region slidably operated with respect to the plurality of through-holes is slid by the stepping motor 240, which is controlled by an electronic controller.

For example, when the cooled warm water is maximally supplied, the controller drives the stepping motor 240 to dispose the one through-hole 231 at the through-holes, through which the cooled warm water is introduced, such that the through-holes through which the cooled warm water is introduced, among the three through-hole of the lower region 210, comes in communication with the one through-hole 231 of the central region 230.

In addition, when the heated warm water is maximally supplied, the controller drives the stepping motor 240 to dispose the one through-hole 231 at the through-hole through which the heated warm water is introduced, such that the through-hole through which the heated warm water is introduced, among the three through-holes of the lower region 210, comes in communication with the one through-hole 231 of the central region 230.

Meanwhile, when the cooled warm water is partially supplied, the controller drives the stepping motor 240 to dispose only a portion of the one through-hole 231 at the through-hole through which the cooled warm water is introduced, such that the through-hole through which the cooled warm water is introduced, among the three through-holes of the lower region 210, comes in partial communication with the one through-hole 231 of the central region 230.

In addition, when the heated warm water is partially supplied, the controller drives the stepping motor 240 to dispose only a portion of the one through-hole 231 at the through-hole through which the heated warm water is introduced, such that the through-hole through which the heated warm water is introduced, among the three through-holes of the lower region 210, comes in partial communication with the one through-hole 231 of the central region 230.

Further, a semiconductor manufacturing apparatus 1000 using the electronic control mixing valve 200 includes the electronic control mixing valve 200 including the lower region 210 having the plurality of through-holes and the introduction ports formed at the lower ends of the plurality of through-holes, respectively, the upper region 220 having the same number of openings as the plurality of through-holes at the region of the lower surface facing the plurality of through-holes and the one discharge port 221 formed at the upper surface, and the central region 230 having the one through-hole 231 configured to bring the upper region 220 in communication with the lower region 210 and slidable with respect to the plurality of through-holes such that the one through-hole 231 brings any one of the plurality of through-holes in communication with the opening corresponding to the one of the plurality of through-holes and blocks the opening that does not correspond to the one of the plurality of through-holes, wherein the one through-hole 231 of the central region 230 is slidably driven by the stepping motor 240, and the plurality of through-holes and the introduction ports disposed at the lower ends of the plurality of through-holes are constituted by the three through-holes through which the cooled warm water, the heated warm water, and the mixed water of the cooled warm water and the heated warm water are introduced, respectively, and the three introduction ports disposed under the three through-holes, respectively, a chuck base 100 configured to dispose a wafer 10 thereon and maintain a uniform temperature upon deposition of the wafer 10, a flowing water supply line 110 configured to supply at least one of the cooled warm water, the heated warm water or the mixed water from the discharge port 221 of the upper region 220 to the chuck base 100, a flowing water discharge line 120 configured to discharge the flowing water from the chuck base 100, a pump 600 configured to circulate the discharged flowing water, a distributor 700 configured to distribute the flowing water circulated by the pump 600 to a first heat exchanger 300a, a second heat exchanger 300b, or the introduction port into which the mixed water is introduced, a cold temperature source 400 configured to cool and discharge the flowing water introduced from the first heat exchanger 300a, and a hot temperature source 500 configured to heat and discharge the flowing water introduced from the second heat exchanger 300b, wherein the first heat exchanger 300a supplies the flowing water distributed by the distributor 700 to the cold temperature source 400 and provides the cooled warm water supplied from the cold temperature source 400 to the introduction port into which the cooled warm water is introduced, and the second heat exchanger 300b supplies the flowing water distributed by the distributor 700 to the hot temperature source 500 and provides the heated warm water supplied from the hot temperature source 500 to the introduction port into which the heated warm water is introduced.

Reviewing an operation of the semiconductor manufacturing apparatus 1000 using the electronic control mixing valve 200, in order to dispose the wafer 10 thereon and maintain a uniform temperature upon deposition of the wafer 10, the chuck base 100 receives at least one of the cooled warm water, the heated warm water and the mixed water from the discharge port 221 of the electronic control mixing valve 200 through the flowing water supply line 110. As described above, the cooled warm water, the heated warm water or the mixed water received from the flowing water supply line 110 is used to maintain the uniform temperature of the chuck base 100 and then is discharged from the chuck base 100 through the flowing water discharge line 120. The flowing water discharged as described above is circulated through the pump 600, and the distributor 700 distributes the flowing water circulated by the pump 600 to the first heat exchanger 300a, the second heat exchanger 300b, or the introduction port into which the mixed water is introduced.

Here, the cold temperature source 400 cools and discharge the flowing water introduced from the first heat exchanger 300a, and the hot temperature source 500 heats and discharge the flowing water introduced from the second heat exchanger 300b.

In addition, the first heat exchanger 300a supplies the flowing water distributed by the distributor 700 to the cold temperature source 400 and provides the cooled warm water received from the cold temperature source 400 to the introduction port of the electronic control mixing valve 200 into which the cooled warm water is introduced, and the second heat exchanger 300b supplies the flowing water distributed by the distributor 700 to the hot temperature source 500 and provides the heated warm water received from the hot temperature source 500 to the introduction port of the electronic control mixing valve 200 into which the heated warm water is introduced.

Meanwhile, the mixed water distributed from the distributor 700 is introduced into the introduction port into which the mixed water of the electronic control mixing valve 200 is introduced.

As described above, the cooled warm water, the heated warm water or the mixed water introduced through the electronic control mixing valve 200 flows from the lower region 210 of the electronic control mixing valve 200 to the upper region 220 through the one through-hole 231 configured to bring the upper region 220 in communication with the lower region 210.

As described above, the valve 200 is slid with respect to the plurality of through-holes such that the one through-hole 231 of the central region 230 brings any one of the plurality of through-holes in communication with the opening corresponding to the one of the plurality of through-holes and blocks the opening that does not correspond to the one of the plurality of through-holes.

Meanwhile, the cooled warm water, the heated warm water or the mixed water flowing from the lower region 210 to the upper region 220 is discharged through the one discharge port 221 disposed at the upper surface of the upper region 220 to be introduced into the chuck base 100 using the flowing water supply line 110.

As described above, a cycle in which the flowing water discharged from the chuck base 100 is introduced into the chuck base 100 again is repeatedly performed.

Meanwhile, it is desirable for the cold temperature source 400 to cool the flowing water distributed by the distributor 700 to −60° C., and the hot temperature source 500 to heat the flowing water distributed by the distributor 700 to 150° C. That is, the reason for cooling the flowing water distributed by the distributor 700 to −60° C. through the cold temperature source 400 is that a different etching effect cannot be exhibited in etching variously this films on the wafer when the flowing water is cooled under the temperature. In addition, the reason for heating the flowing water distributed by the distributor 700 to 150° C. through the hot temperature source 500 is that a deposition effect of a CVD thin film cannot be exhibited upon deposition of various thin films on the wafer when the flowing water is heated over the temperature.

According to the electronic control mixing valve 200 and the semiconductor manufacturing apparatus using the same in accordance with the embodiment of the present invention, as the cooled warm water, the heated warm water and the mixed water are individually supplied through the electronic control mixing valve 200 having multiple ports and the recirculation oils are supplied using the slidable mixing valve by the stepping motor 240 controlled by the electronic controller, the temperature of the chuck base 100 can be finely controlled.

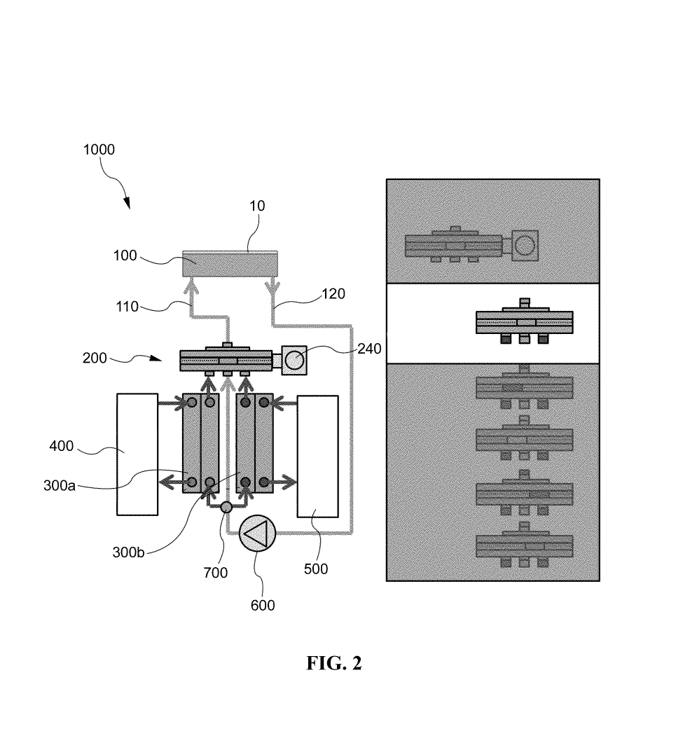

Next, FIG. 2 is a view showing a circulating operation of the mixed water in the semiconductor manufacturing apparatus using the slidable mixing valve according to the embodiment of the present invention.

Referring to FIG. 2, when the mixed water is maximally supplied, among the three through-holes of the lower region 210, the through-hole (the central through-hole in the drawing) through which the mixed water is introduced is in communication with the one through-hole 231 of the central region 230. Here, the electronic controller drives the stepping motor 240 to dispose the one through-hole 231 of the central region 230 at the through-hole through which the mixed water is introduced. As described above, when the one through-hole 231 is disposed at the through-hole through which the mixed water is introduced, the lower region 210 comes in communication with the upper region 220 by the one through-hole 231 of the central region 230, and the mixed water is discharged through the one discharge port 221 disposed at the upper surface of the upper region 220 to enter the flowing water supply line 110. Of course, when the one through-hole 231 is disposed at the through-hole through which the mixed water is introduced, the through-hole through which the cooled warm water or the heated warm water is introduced is blocked so that the cooled warm water or the heated warm water cannot flow to the upper region 220.

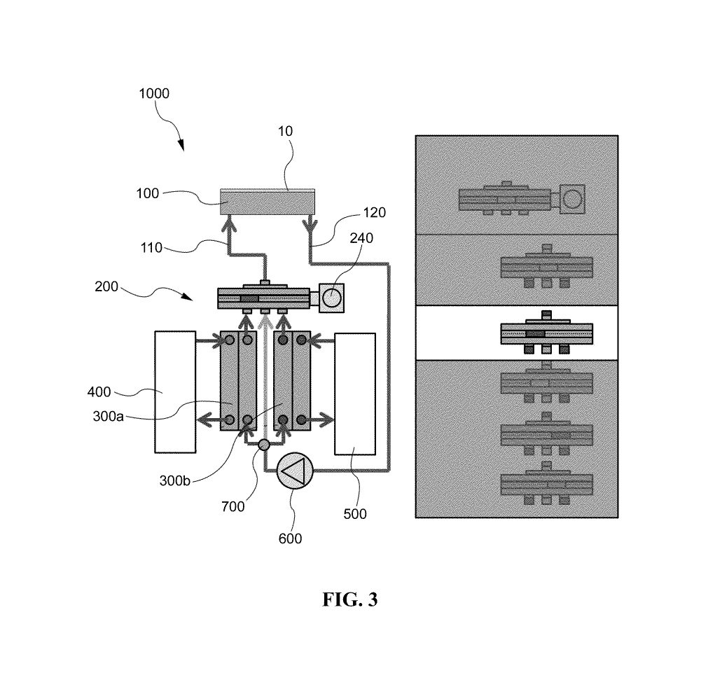

Next, FIG. 3 is a view showing a circulating operation of the cooled warm water maximally introduced from the semiconductor manufacturing apparatus using the slidable mixing valve according to the embodiment of the present invention.

Referring to FIG. 3, when the cooled warm water is maximally supplied, among the three through-holes of the lower region 210, the through-hole (the left through-hole in the drawing) through which the cooled warm water is introduced is in communication with the one through-hole 231 of the central region 230. Here, when the electronic controller drives the stepping motor 240 to dispose the one through-hole 231 of the central region 230 at the through-hole through which the cooled warm water is introduced, the lower region 210 is in communication with the upper region 220 by the one through-hole 231 of the central region 230, and the cooled warm water is discharged through the one discharge port 221 disposed at the upper surface of the upper region 220 to enter the flowing water supply line 110. Of course, when the one through-hole 231 is disposed at the through-hole through which the cooled warm water is introduced, the through-hole through which the heated warm water or the mixed water is introduced is blocked, and thus, the heated warm water or the mixed water cannot flow to the upper region 220.

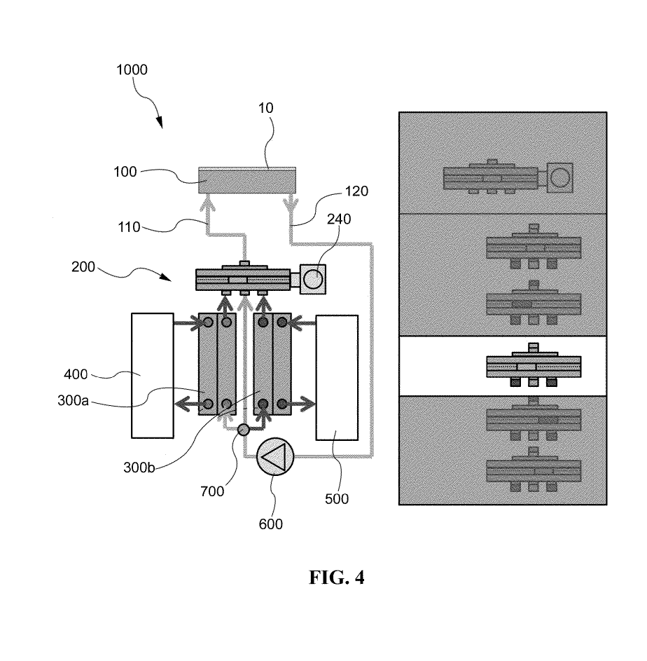

Next, FIG. 4 is a view showing a circulating operation of the cooled warm water partially introduced from the semiconductor manufacturing apparatus using the slidable mixing valve according to the embodiment of the present invention.

Referring to FIG. 4, when the cooled warm water is partially supplied, among the three through-holes of the lower region 210, the through-hole (the left through-hole of the drawing) through which the cooled warm water is introduced comes in partial communication with the one through-hole 231 of the central region 230. Here, when the electronic controller drives the stepping motor 240 to dispose only a portion of the one through-hole 231 of the central region 230 at the through-hole through which the cooled warm water is introduced, the lower region 210 is in partial communication with the upper region 220 by the one through-hole 231 of the central region 230, and thus, the cooled warm water is partially discharged through the one discharge port 221 disposed at the upper surface of the upper region 220 to enter the flowing water supply line 110. Of course, when the one through-hole 231 is disposed at the through-hole through which the cooled warm water is partially introduced, the through-hole through which the heated warm water or the mixed water is introduced is blocked, the heated warm water or the mixed water cannot flow to the upper region 220.

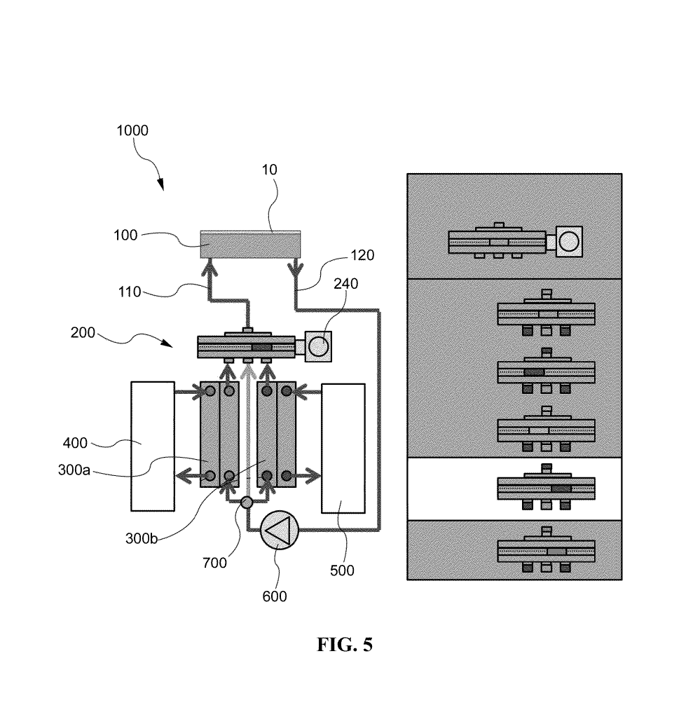

Next, FIG. 5 is a view showing a circulating operation of the heated warm water maximally introduced from the semiconductor manufacturing apparatus using the slidable mixing valve according to the embodiment of the present invention.

Referring to FIG. 5, when the heated warm water is maximally supplied, among the three through-holes of the lower region 210, the through-hole (the right through-hole of the drawing) through which the heated warm water is introduced comes in communication with the one through-hole 231 of the central region 230. Here, when the electronic controller drives the stepping motor 240 to dispose the one through-hole 231 of the central region 230 at the through-hole through which the heated warm water is introduced, the lower region 210 is in communication with the upper region 220 by the one through-hole 231 of the central region 230, and the heated warm water is discharged through the one discharge port 221 disposed at the upper surface of the upper region 220 to enter the flowing water supply line 110. Of course, when the one through-hole 231 is disposed at the through-hole through which the heated warm water is introduced, the through-hole through which the cooled warm water or the mixed water is blocked, and the cooled warm water or the mixed water cannot flow to the upper region 220.

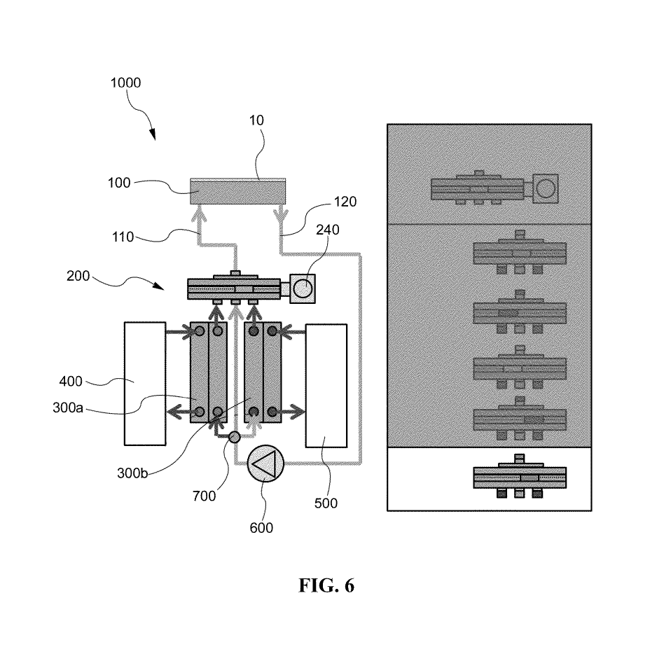

Next, FIG. 6 is a view showing a circulating operation of the heated warm water partially introduced from the semiconductor manufacturing apparatus using the slidable mixing valve according to the embodiment of the present invention.

Referring to FIG. 6, when the heated warm water is partially supplied, among the three through-holes of the lower region 210, the through-hole (the right through-hole of the drawing) through which the heated warm water is introduced comes in partial communication with the one through-hole 231 of the central region 230. Here, when the electronic controller drives the stepping motor 240 to dispose only a portion of the one through-hole 231 of the central region 230 at the through-hole through which the heated warm water is introduced, the lower region 210 is in partial communication with the upper region 220 by the one through-hole 231 of the central region 230, and the heated warm water is partially discharged through the one discharge port 221 disposed at the upper surface of the upper region 220 to enter the flowing water supply line 110. Of course, when the one through-hole 231 is disposed at the through-hole through which the heated warm water is partially introduced, the through-hole through which the cooled warm water or the mixed water is blocked, and the cooled warm water or the mixed water cannot flow to the upper region 220.

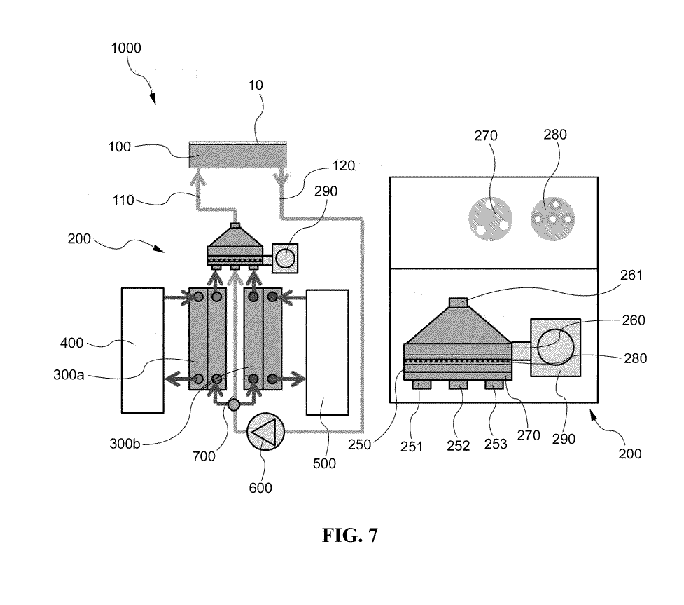

Next, FIG. 7 is a general configuration view of the semiconductor manufacturing apparatus using the rotatable mixing valve according to the embodiment of the present invention.

Referring to FIG. 7, the electronic control mixing valve 200 according to the embodiment of the present invention includes a lower region 250 having a lower flat plate 270 in which a plurality of openings are formed along an outer circumferential side of a lower surface and an upper flat plate 280 having introduction ports provided at the openings, disposed at a center of an upper surface, and having a plurality of openings disposed along an outer circumferential side of the upper surface, and an upper region 260 having a through-hole in communication with the opening of the center of the upper flat plate 280 and one discharge port 261 formed on the through-hole, wherein the upper flat plate 280 of the lower region 250 is rotatably driven by a stepping motor 290.

A positional relation and an operational relation thereof will be described in detail.

The electronic control mixing valve 200 according to the embodiment of the present invention includes the lower region 250 having the lower flat plate 270 in which the plurality of openings are formed along the outer circumferential side of the lower surface and the upper flat plate 280 having the introduction ports provided at the openings, disposed at the center of the upper surface, and having the plurality of openings disposed along the outer circumferential side of the upper surface, and the upper region 260 having the through-hole in communication with the opening of the center of the upper flat plate 280 and one discharge port 261 formed on the through-hole.

That is, the electronic control mixing valve 200 according to the embodiment is constituted by two stages of the lower region 250 and the upper region 260, the lower region 250 includes the lower flat plate 270 and the upper flat plate 280, and the upper flat plate 280 of the lower region 250 is rotatably driven by the stepping motor 290.

For example, when any one opening of the plurality of openings disposed along the outer circumferential side of the upper flat plate 280 overlaps any one opening of the plurality of openings of the lower flat plate 270, the upper flat plate 280 of the lower region 250 is rotatably driven by the stepping motor 290 such that the other openings of the plurality of openings of the upper flat plate 280 do not overlap the other openings of the plurality of openings of the lower flat plate 270.

In addition, the plurality of openings disposed along the outer circumferential side of the upper flat plate 280 may be three, and plurality of openings of the lower flat plate 270 may also be three. Accordingly, the introduction ports corresponding to the three openings are constituted by three introduction ports through which the cooled warm water, the heated warm water and the mixed water of the cooled warm water and the heated warm water are introduced, respectively.

Meanwhile, the three openings of the lower flat plate 270 are disposed along the outer circumferential side about a center of the upper surface at 120° intervals.

The upper flat plate 280 of the electronic control mixing valve 200 disposed as described above is rotated by the stepping motor 290 to overlap or not to overlap the plurality of openings formed in the lower flat plate 270.

In addition, the stepping motor 290 is controlled by an electronic controller.

For example, when the cooled warm water is maximally supplied, the controller drives the stepping motor 290 to cause the one opening of the upper flat plate 280 to overlap the opening of the lower flat plate 270 through which the cooled warm water is introduced such that the opening through which the cooled warm water is introduced, among the three openings of the lower flat plate 270, comes in communication with any one opening of the three openings of the upper flat plate 280.

In addition, when the heated warm water is maximally supplied, the controller drives the stepping motor 290 to cause the one opening of the upper flat plate 280 to overlap the opening of the lower flat plate 270 through which the heated warm water is introduced such that the opening through which the heated warm water is introduced, among the three openings of the lower region 250, comes in communication with any one opening of the three openings of the upper flat plate 280.

Meanwhile, in driving the electronic control mixing valve 200 using the stepping motor 290 controlled by the electronic controller, when the cooled warm water is partially supplied, the controller drives the stepping motor 290 to cause only a portion of the one opening of the upper flat plate 280 to overlap the opening of the lower flat plate 270 through which the cooled warm water is introduced such that the opening through which the cooled warm water is introduced, among the three openings of the lower flat plate 270 comes in partial communication with any one opening of the three openings of the upper flat plate 280.

In addition, when the heated warm water is partially supplied, the controller drives the stepping motor 290 to cause only a portion of the one opening of the upper flat plate 280 to overlap the opening of the lower flat plate 270 through which the heated warm water is introduced such that the opening through which the heated warm water is introduced, among the three openings of the lower region 250, comes in partial communication with any one opening of the three openings of the upper flat plate 280.

Meanwhile, the semiconductor manufacturing apparatus 1000 using the electronic control mixing valve 200 according to the embodiment of the present invention includes the electronic control mixing valve 200 including the lower region 250 having the lower flat plate 270 in which the plurality of openings are formed along the outer circumferential side of the lower surface and the upper flat plate 280 having the introduction ports provided at the openings and the plurality of openings disposed at the center of the upper surface along the outer circumferential side of the upper surface, and the upper region 260 having the through-hole in communication with the opening of the center of the upper flat plate 280 and the one discharge port 261 formed on the through-hole, wherein the upper flat plate 280 of the lower region 250 is rotatably driven by the stepping motor 290, and when any one opening of the plurality of openings disposed along the outer circumferential side of the upper flat plate 280 overlaps any one opening of the plurality of openings of the lower flat plate 270, another openings of the plurality of openings of the upper flat plate 280 does not overlap another opening of the plurality of openings of the lower flat plate 270, the chuck base 100 configured to dispose the wafer 10 thereon and configured to maintain a uniform temperature upon deposition of the wafer 10, the flowing water supply line 110 configured to supply at least one of the cooled warm water, the heated warm water and the mixed water from the discharge port 261 of the upper region 260 to the chuck base 100, the flowing water discharge line 120 configured to discharge the flowing water from the chuck base 100, the pump 600 configured to circulate the discharged flowing water, the distributor 700 configured to distribute the flowing water circulated by the pump 600 to the first heat exchanger 300a, the second heat exchanger 300b, or the introduction port into which the mixed water is introduced, the cold temperature source 400 configured to cool and discharge the flowing water introduced from the first heat exchanger 300a, and the hot temperature source 500 configured to heat and discharge the flowing water introduced from the second heat exchanger 300b, wherein the first heat exchanger 300a supplies the flowing water distributed by the distributor 700 to the cold temperature source 400 and provides the cooled warm water received from the cold temperature source 400 to the introduction port into which the cooled warm water is introduced, and the second heat exchanger 300b supplies the flowing water distributed by the distributor 700 to the hot temperature source 500 and provides the heated warm water received from the hot temperature source 500 to the introduction port into which the heated warm water is introduced.

Reviewing an operational relation of the semiconductor manufacturing apparatus 1000 using the electronic control mixing valve 200, in order to dispose the wafer 10 thereon and maintain a uniform temperature upon deposition of the wafer 10, the chuck base 100 receives at least one of the cooled warm water, the heated warm water and the mixed water from the discharge port 261 of the electronic control mixing valve 200 through the flowing water supply line 110. The cooled warm water, the heated warm water or the mixed water provided from the flowing water supply line 110 is used to maintain the uniform temperature of the chuck base 100 and then discharged from the chuck base 100 through the flowing water discharge line 120. The discharged flowing water is circulated through the pump 600, and the flowing water circulated by the pump 600 is distributed by the distributor 700 to the first heat exchanger 300a, the second heat exchanger 300b or the introduction port into which the mixed water is introduced.

Here, the cold temperature source 400 cools and discharge the flowing water flowing from the first heat exchanger 300a, and the hot temperature source 500 heats and discharges the flowing water introduced from the second heat exchanger 300b.

In addition, the first heat exchanger 300a supplies the flowing water distributed by the distributor 700 to the cold temperature source 400 and provides the cooled warm water received from the cold temperature source 400 to the introduction port of the electronic control mixing valve 200 through which the cooled warm water is introduced, and the second heat exchanger 300b supplies the flowing water distributed by the distributor 700 to the hot temperature source 500 and provides the heated warm water received from the hot temperature source 500 to the introduction port of the electronic control mixing valve 200 through which the heated warm water is introduced.

Meanwhile, the mixed water distributed from the distributor 700 is introduced into the introduction port of the electronic control mixing valve 200 into which the mixed water is introduced.

The cooled warm water, the heated warm water or the mixed water introduced into the introduction port is moved to the lower region 250 of the electronic control mixing valve 200. The lower region 250 includes the lower flat plate 270 having the plurality of openings (three openings in the embodiment) along the outer circumferential side of the lower surface, and the upper flat plate 280 having the introduction ports provided to the openings, disposed at the center of the upper surface, and having the plurality of openings disposed along the outer circumferential side of the upper surface.

The lower region 250 has the through-hole in communication with the opening of the center of the upper flat plate 280, and constitutes the electronic control mixing valve 200 with the upper region 260 having the one discharge port 261 formed on the through-hole.

In addition, as the upper flat plate 280 of the lower region 250 is rotatably driven by the stepping motor 290 controlled by the electronic controller, when any one opening of the plurality of openings disposed along the outer circumferential side of the upper flat plate 280 overlaps any one opening of the plurality of openings of the lower flat plate 270, another opening of the plurality of openings of the upper flat plate 280 is blocked not to overlap another opening of the plurality of openings of the lower flat plate 270.

Meanwhile, the cooled warm water, the heated warm water or the mixed water moved from the lower region 250 to the upper region 260 is discharged through the one discharge port 261 disposed at the upper surface of the upper region 260 to be introduced into the chuck base 100 using the flowing water supply line 110.

As described above, a cycle in which the flowing water discharged from the chuck base 100 is introduced into the chuck base 100 again is repeatedly performed.

Meanwhile, the cold temperature source 400 may cool the flowing water distributed by the distributor 700 to −60° C., and the hot temperature source 500 may heat the flowing water distributed by the distributor 700 to 150° C.

According to the electronic control mixing valve 200 and the semiconductor manufacturing apparatus using the same according to the embodiment of the present invention, as cooled warm water, the heated warm water and the mixed water are individually supplied through the electronic control mixing valve 200 having multiple ports and the stepping motor 290 controlled by the electronic controller is used, the temperature of the chuck base 100 can be finely controlled by supplying the recirculation oils using the rotatable mixing valve.

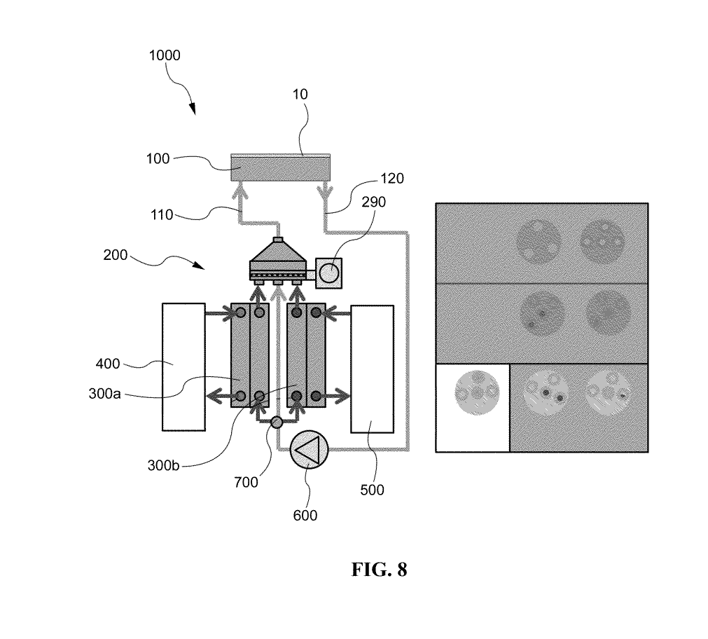

Next, FIG. 8 is a view showing a circulating operation of the mixed water of the semiconductor manufacturing apparatus using the rotatable mixing valve according to the embodiment of the present invention.

Referring to FIG. 8, when the mixed water is maximally supplied, the controller drives the stepping motor 290 to cause the one opening of the upper flat plate 280 to overlap the opening of the lower flat plate 270 through which the mixed water is introduced such that the opening through (the central opening of the drawing) which the mixed water is introduced, among the three openings of the lower flat plate 270, comes in communication with one opening of the three openings of the upper flat plate 280. As described above, when the one opening of the upper flat plate 280 is disposed to overlap the opening of the lower flat plate 270 through which the mixed water is introduced, as the lower region 250 is in communication with the upper region 260, the mixed water is discharged through the one discharge port 261 disposed at the upper surface of the upper region 260 to enter the flowing water supply line 110. Of course, when the one opening of the upper flat plate 280 is disposed to overlap the opening of the lower flat plate 270 through which the mixed water is introduced, the opening through which the cooled warm water or the heated warm water is introduced is blocked, and the cooled warm water or the heated warm water cannot flow to the upper region 260.

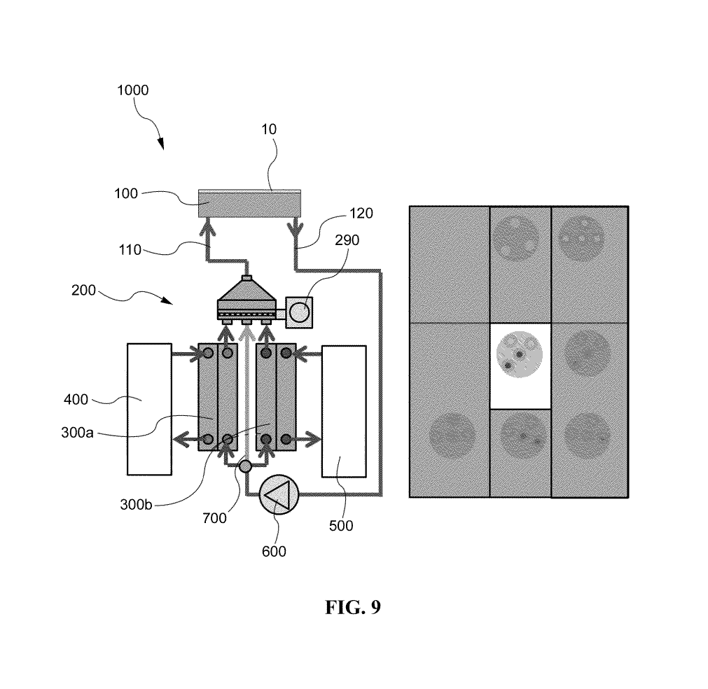

Next, FIG. 9 is a view showing a circulating operation of the cooled warm water maximally introduced from the semiconductor manufacturing apparatus using the rotatable mixing valve according to the embodiment of the present invention.

Referring to FIG. 9, when the cooled warm water is maximally supplied, the controller drives the stepping motor 290 to cause the one opening of the upper flat plate 280 to overlap the opening of the lower flat plate 270 through which the cooled warm water is introduced such that the opening (the left opening of the drawing) through which the cooled warm water is introduced, among the three openings of the lower flat plate 270, comes in communication with the one opening of the three openings of the upper flat plate 280. As described above, when the one opening of the upper flat plate 280 is disposed to overlap the opening of the lower flat plate 270 through which the cooled warm water is introduced, as the lower region 250 is in communication with the upper region 260, the cooled warm water is discharged through the one discharge port 261 disposed at the upper surface of the upper region 260 to enter the flowing water supply line 110. Of course, when the one opening of the upper flat plate 280 is disposed to overlap the opening of the lower flat plate 270 through which the cooled warm water is introduced, the opening through which the mixed water or the heated warm water is introduced is blocked, and the mixed water or the heated warm water cannot move to the upper region 260.

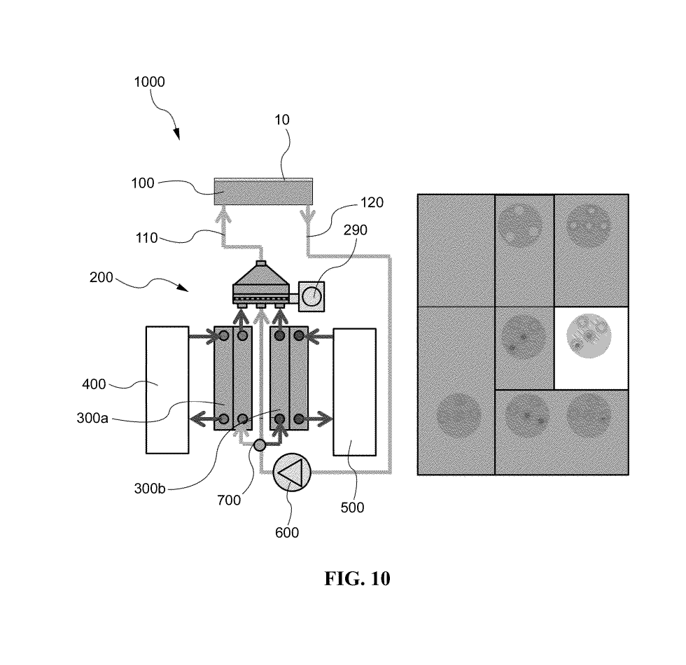

Next, FIG. 10 is a view showing a circulating operation of the cooled warm water partially introduced from the semiconductor manufacturing apparatus using the rotatable mixing valve according to the embodiment of the present invention.

Referring to FIG. 10, when the cooled warm water is partially supplied, the controller drives the stepping motor 290 to cause the one opening of the upper flat plate 280 to partially overlap the opening of the lower flat plate 270 through which the cooled warm water is introduced such that the opening (the left opening of the drawing) through which the cooled warm water is introduced, among the three openings of the lower flat plate 270, comes in partial communication with the one opening of the three openings of the upper flat plate 280. As described above, when the one opening of the upper flat plate 280 is disposed to partially overlap the opening of the lower flat plate 270 through which the cooled warm water is introduced, as the lower region 250 is in partial communication with the upper region 260, the cooled warm water is discharged through the one discharge port 261 disposed at the upper surface of the upper region 260 to enter the flowing water supply line 110. Of course, when the one opening of the upper flat plate 280 is disposed to partially overlap the opening of the lower flat plate 270 through which the cooled warm water is introduced, the opening through which the mixed water or the heated warm water is introduced is blocked, and the mixed water or the heated warm water cannot flow to the upper region 260.

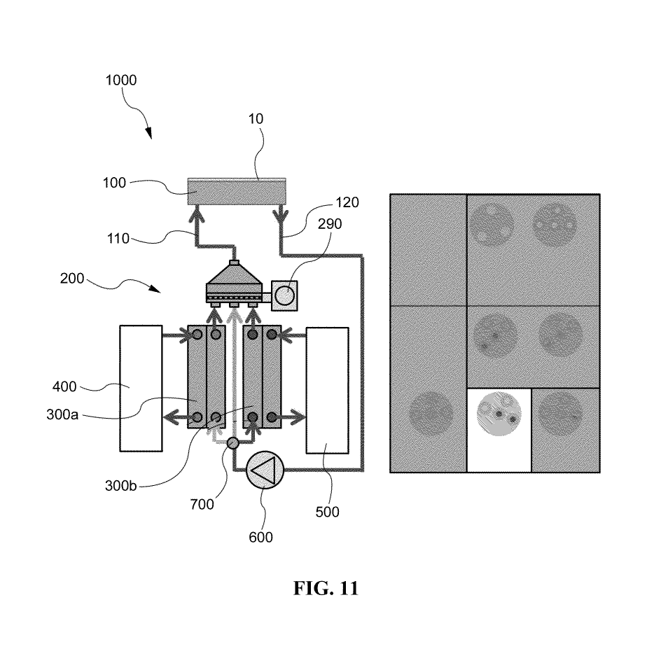

Next, FIG. 11 is a view showing a circulating operation of the heated warm water maximally introduced from the semiconductor manufacturing apparatus using the rotatable mixing valve according to the embodiment of the present invention.

Referring to FIG. 11, when the heated warm water is maximally supplied, the controller drives the stepping motor 290 to cause the one opening of the upper flat plate 280 to overlap the opening of the lower flat plate 270 through which the heated warm water is introduced such that the opening (the right opening of the drawing) through which the heated warm water is introduced, among the three openings of the lower flat plate 270, comes in communication with the one opening of the three openings of the upper flat plate 280. As described above, when the one opening of the upper flat plate 280 is disposed to overlap the opening of the lower flat plate 270 through which the heated warm water is introduced, as the lower region 250 is in communication with the upper region 260, the heated warm water is discharged through the one discharge port 261 disposed at the upper surface of the upper region 260 to enter the flowing water supply line 110. Of course, when the one opening of the upper flat plate 280 is disposed to overlap the opening of the lower flat plate 270 through which the heated warm water is introduced, the opening through which the mixed water or the cooled warm water is introduced is blocked, and the mixed water or the cooled warm water cannot flow to the upper region 260.

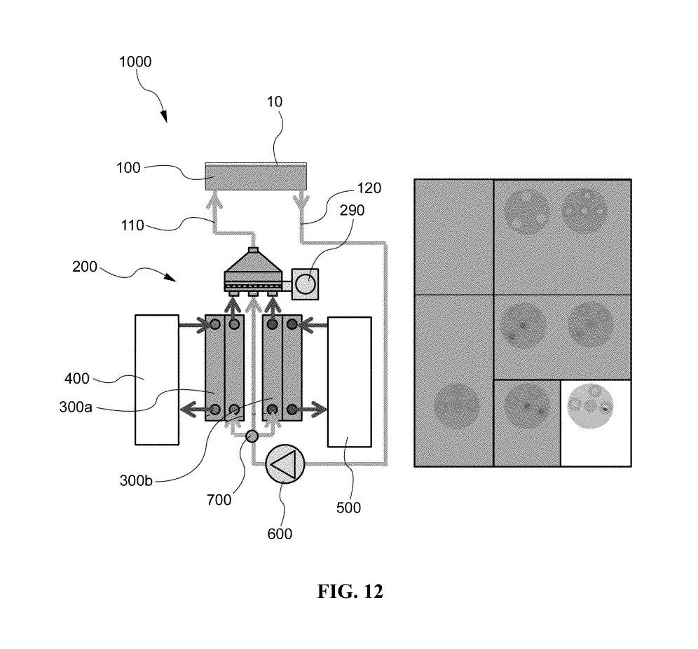

FIG. 12 is a view showing a circulating operation of the heated warm water partially introduced from the semiconductor manufacturing apparatus using the rotatable mixing valve according to the embodiment of the present invention.

Referring to FIG. 12, when the heated warm water is partially supplied, the controller drives the stepping motor 290 to cause the one opening of the upper flat plate 280 to partially overlap the opening of the lower flat plate 270 through which the heated warm water is introduced such that the opening (the left opening of the drawing) through which the heated warm water is introduced, among the three openings of the lower flat plate 270, comes in partial communication with the one opening of the three openings of the upper flat plate 280. As described above, when the one opening of the upper flat plate 280 is disposed to partially overlap the opening of the lower flat plate 270 through which the heated warm water is introduced, as the lower region 250 is in partial communication with the upper region 260, the heated warm water is discharged through the one discharge port 261 disposed at the upper surface of the upper region 260 to enter the flowing water supply line 110. Of course, when the one opening of the upper flat plate 280 is disposed to partially overlap the opening of the lower flat plate 270 through which the heated warm water is introduced, the opening through which the mixed water or the cooled warm water is introduced is blocked, and the mixed water or the cooled warm water cannot flow to the upper region 260.

As can be seen from the foregoing, as the recirculation oils are supplied using the slidable mixing valve or the rotatable mixing valve, which is electronically controlled, it is possible to provide the electronic control mixing valve and the semiconductor manufacturing apparatus using the same that are capable of controlling the temperature of the chuck base.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. An electronic control mixing valve comprising:
a lower region having a plurality of through-holes and introduction ports formed at lower ends of the plurality of through-holes, respectively;
an upper region having the same number of openings as the plurality of through-holes and formed at a region of a lower surface facing the plurality of through-holes, and one discharge port formed at an upper surface; and
a central region having one through-hole configured to bring the upper region in communication with the lower region, and slidable with respect to the plurality of through-holes such that the one through-hole brings any one of the plurality of through-holes in communication with the opening corresponding to the one of the plurality of through-holes and blocks the opening that does not correspond to the one of the plurality of through-holes,
wherein the one through-hole of the central region is slidably driven by a stepping motor.

2. The electronic control mixing valve according to claim 1, wherein the plurality of through-holes and the introduction ports disposed at the lower ends of the plurality of through-holes are constituted by the three through-holes through which cooled warm water, heated warm water and mixed water of the cooled warm water and the heated warm water are introduced, respectively, and three introduction ports disposed under the three through-holes, respectively.

3. The electronic control mixing valve according to claim 2, wherein the stepping motor is controlled by a controller,
when the cooled warm water is maximally supplied, the controller drives the stepping motor to dispose the one through-hole at the through-hole through which the cooled warm water is introduced such that the through-hole through which the cooled warm water is introduced, among the three through-holes of the lower region, comes in communication with the one through-hole of the central region, and
when the heated warm water is maximally supplied, the controller drives the stepping motor to dispose the one through-hole at the through-hole through which the heated warm water is introduced such that the through-hole through which the heated warm water is introduced, among the three through-holes of the lower region, comes in communication with the one through-hole of the central region.

4. The electronic control mixing valve according to claim 2, wherein the stepping motor is controlled by a controller,
when the cooled warm water is partially supplied, the controller drives the stepping motor to dispose only a portion of the one through-hole at the through-hole through which the cooled warm water is introduced such that the through-hole through which the cooled warm water is introduced, among the three through-holes of the lower region, comes in partial communication with the one through-hole, and
when the heated warm water is partially supplied, the controller drives the stepping motor to dispose only a portion of the one through-hole at the through-hole through which the heated warm water is introduced such that the through-hole through which the heated warm water is introduced, among the three through-holes of the lower region, comes in partial communication with the one through-hole of the central region.

5. An electronic control mixing valve comprising:
a lower region having a lower flat plate in which a plurality of openings are formed along an outer circumferential side of a lower surface, and an upper flat plate having introduction ports provided at the openings, respectively, disposed at a center of an upper surface, and having a plurality of opening disposed along an outer circumferential side of the upper surface; and
an upper region having a through-hole in communication with an opening of a center of the upper flat plate and one discharge port formed on the through-hole,
wherein the upper flat plate of the lower region is rotatably driven by a stepping motor.

6. The electronic control mixing valve according to claim 5, wherein, when any one opening of the plurality of openings disposed along the outer circumferential side of the upper flat plate overlaps any one opening of the plurality of openings of the lower flat plate, another opening of the plurality of openings of the upper flat plate does not overlap another opening of the plurality of openings of the lower flat plate.

7. The electronic control mixing valve according to claim 6, wherein the plurality of openings disposed along the outer circumferential side of the upper flat plate are constituted by three openings,
the plurality of openings of the lower flat plate are constituted by three openings, and
the introduction ports corresponding to the three openings are constituted by three introduction ports through which cooled warm water, heated warm water, and mixed water of the cooled warm water and the heated warm water are introduced, respectively.

8. The electronic control mixing valve according to claim 7, wherein the three openings of the lower flat plate are disposed along the outer circumferential side about a center of the upper surface at 120° intervals.

9. The electronic control mixing valve according to claim 8, wherein the stepping motor is controlled by a controller,
when the cooled warm water is maximally supplied, the controller drives the stepping motor to cause the one opening of the upper flat plate to overlap the opening of the lower flat plate through which the cooled warm water is introduced such that the opening through which the cooled warm water is introduced, among the three openings of the lower flat plate, comes in communication with any one opening of the three openings of the upper flat plate, and
when the heated warm water is maximally supplied, the controller drives the stepping motor to cause the one opening of the upper flat plate to overlap the opening of the lower flat plate through which the heated warm water is introduced such that the opening through which the heated warm water is introduced, among the three openings of the lower region, comes in communication with any one opening of the three openings of the upper flat plate.

10. The electronic control mixing valve according to claim 8, wherein the stepping motor is controlled by a controller,
when the cooled warm water is partially supplied, the controller drives the stepping motor to cause only a portion of the one opening of the upper flat plate to overlap the opening of the lower flat plate through which the cooled warm water is introduced such that the opening through which the cooled warm water is introduced, among the three openings of the lower flat plate, comes in partial communication with any one opening of the three openings of the upper flat plate, and
when the heated warm water partially supplied, the controller drives the stepping motor to cause only a portion of the one opening of the upper flat plate to overlap the opening of the lower flat plate through which the heated warm water is introduced such that the opening through which the heated warm water is introduced, among the three openings of the lower region, comes in partial communication with any one opening of the three openings of the upper flat plate.

11. A semiconductor manufacturing apparatus using an electronic control mixing valve, the apparatus comprising:
an electronic control mixing valve comprising a lower region having a plurality of through-holes and introduction ports disposed at lower ends of the plurality of through-holes, respectively, an upper region having the same number of openings as the plurality of through-holes and formed at a region of a lower surface facing the plurality of through-holes and one discharge port formed at an upper surface, and a central region having one through-hole configured to bring the upper region in communication with the lower region and slidable with respect to the plurality of through-holes such that the one through-hole brings any one of the plurality of through-holes in communication with the opening corresponding to the one of the plurality of through-holes and blocks the opening that does not correspond to the one of the plurality of through-holes, wherein the one through-hole of the central region is slidably driven by a stepping motor, and the plurality of through-holes and the introduction ports disposed at the lower ends of the plurality of through-holes are constituted by three through-holes through which cooled warm water, heated warm water, and mixed water of the cooled warm water and the heated warm water are introduced, respectively, and three introduction ports disposed under the three through-holes;
a chuck base configured to dispose a wafer thereon and maintain a uniform temperature upon deposition of the wafer;
a flowing water supply line configured to supply at least one of the cooled warm water, the heated warm water and the mixed water from the discharge port of the upper region to the chuck base;
a flowing water discharge line configured to discharge the flowing water from the chuck base;
a pump configured to circulate the discharged flowing water;
a distributor configured to distribute the flowing water circulated by the pump to a first heat exchanger, a second heat exchanger, or the introduction port into which the mixed water is introduced;
a cold temperature source configured to cool and discharge the flowing water introduced from the first heat exchanger; and
a hot temperature source configured to heat and discharge the flowing water introduced from the second heat exchanger,
wherein the first heat exchanger supplies the flowing water distributed by the distributor to the cold temperature source and provides the cooled warm water received from the cold temperature source to the introduction port into which the cooled warm water is introduced, and
the second heat exchanger supplies the flowing water distributed by the distributor to the hot temperature source and provides the heated warm water received from the hot temperature source to the introduction port into which the heated warm water is introduced.

12. The semiconductor manufacturing apparatus using the electronic control mixing valve according to claim 11, wherein the cold temperature source cools the flowing water distributed by the distributor to −60° C.

13. The semiconductor manufacturing apparatus using the electronic control mixing valve according to claim 11, wherein the hot temperature source heats the flowing water distributed by the distributor to 150° C.

14. A semiconductor manufacturing apparatus using an electronic control mixing valve, the apparatus comprising:
an electronic control mixing valve comprising a lower region having a lower flat plate in which a plurality of openings are formed along an outer circumferential side of a lower surface and an upper flat plate having introduction ports provided at the openings, respectively, disposed at a center of an upper surface, and having a plurality of opening disposed along an outer circumferential side of the upper surface, and an upper region having a through-hole in communication with an opening of a center of the upper flat plate and one discharge port formed on the through-hole, wherein the upper flat plate of the lower region is rotatably driven by a stepping motor, and when any one opening of the plurality of openings disposed along the outer circumferential side of the upper flat plate overlaps any one opening of the plurality of openings of the lower flat plate, another opening of the plurality of openings of the upper flat plate does not overlap another opening of the plurality of openings of the lower flat plate;
a chuck base configured to dispose a wafer thereon and maintain a uniform temperature upon deposition of the wafer;
a flowing water supply line configured to supply at least one of cooled warm water, heated warm water and mixed water from the discharge port of the upper region to the chuck base;
a flowing water discharge line configured to discharge the flowing water from the chuck base;
a pump configured to circulate the discharged flowing water;
a distributor configured to distribute the flowing water circulated by the pump to a first heat exchanger, a second heat exchanger or the introduction port into which the mixed water is introduced;
a cold temperature source configured to cool and discharge the flowing water introduced from the first heat exchanger; and
a hot temperature source configured to heat and discharge the flowing water introduced from the second heat exchanger,
wherein the first heat exchanger supplies the flowing water distributed by the distributor to the cold temperature source and provides the cooled warm water received from the cold temperature source to the introduction port into which the cooled warm water is introduced, and
the second heat exchanger supplies the flowing water distributed by the distributor to the hot temperature source and provides the heated warm water received from the hot temperature source to the introduction port into which the heated warm water is introduced.

15. The semiconductor manufacturing apparatus using the electronic control mixing valve according to claim 14, wherein the cold temperature source cools the flowing water distributed by the distributor to −60° C.

16. The semiconductor manufacturing apparatus using the electronic control mixing valve according to claim 14, wherein the hot temperature source heats the flowing water distributed by the distributor to 150° C.
